(19) United States
(12) Patent Application Publication
(10) Pub. No.: US 2014/0266244 A1
(43) Pub. Date: Sep. 18, 2014

(54) SYSTEMS AND METHODS FOR REAL-TIME MONITORING OF DISPLAYS DURING INSPECTION

(71) Applicant: Photon Dynamics Inc., San Jose, CA (US)

(72) Inventors: Viacheslav MINAEV, Sunnyvale, CA (US); Raul Albert MARTIN, San Jose, CA (US); Thomas E. WISHARD, Santa Cruz, CA (US); Michael Sean CASSADY, San Jose, CA (US); Jongho LEE, San Jose, CA (US); Thomas H. BAILEY, San Jose, CA (US); Sriram KRISHNASWAMI, Saratoga, CA (US)

(73) Assignee: Photon Dynamics Inc., San Jose, CA (US)

(21) Appl. No.: 14/214,958

(22) Filed: Mar. 16, 2014

Related U.S. Application Data
(60) Provisional application No. 61/801,787, filed on Mar. 15, 2013.

(51) Int. Cl. G01R 31/28

(52) U.S. Cl. CPC G01R 31/28
USPC 324/537

(57) ABSTRACT

Described are techniques for maintaining reliable and reproducible conditions for panel inspection, i.e. pixel and line defect detection, while at the same time preventing large-scale panel damage. One implementation involves an apparatus for identifying a defect in an electronic circuit incorporating a circuit driving module configured to apply an electrical test signal to the electronic circuit; a defect detection module configured to identify the defect in the electronic circuit based at least on the applied electrical test signal; a signal monitoring module configured to measure the electrical test signal at the electronic circuit; and a control module operatively coupled to the signal monitoring module and the circuit driving module and configured to control at least the circuit driving module based on the electrical test signal measured at the electronic circuit.

### CROSS-REFERENCE TO RELATED PATENT APPLICATION

The present U.S. patent application relies upon, claims the benefit of priority from, and is a non-provisional of U.S. provisional patent application No. 61/801,787 filed on Mar. 15, 2013, the entire disclosure of which is incorporated by reference herein.

### BACKGROUND OF THE INVENTION

1. Field of the Invention

The present invention relates generally to the field of electrical inspection of electronic devices and in particular to inspection of both rigid and flexible Liquid Crystal (LC) and Organic Light Emitting Diode (OLED) displays as well as the systems used in the inspection and defect detection.

2. Description of the Related Art

Liquid crystal display (LCD) panels incorporate liquid crystals that exhibit electric-field dependent light modulating properties. They are used most frequently to display images and other information in a variety of devices ranging from fax machines, cell phones, tablet and laptop computer screens, to large screen, high-definition TVs. Active matrix LCD panels are complex layered structures consisting of several functional layers: one or more layers of polarizing film; a TFT glass substrate incorporating thin-film transistors, storage capacitors, pixel electrodes and interconnect wiring a color filter glass substrate incorporating a black matrix and a color filter array and a transparent common electrode; an orientation film made of polyimide; and the actual liquid crystal material incorporating plastic/glass spacers to maintain proper LCD cell thickness.

LCD panels are manufactured under highly controlled conditions in a clean room environment to maximize yield. Nonetheless, some LCDs may have to be discarded because of manufacturing flaws in the assembled product.

In order to improve LCD panel production yield, multiple inspection and repair steps are implemented during the entire manufacturing process of LCD panels. Among those, one of the most critical inspection steps is array testing, the electrical inspection step performed at the end of the TFT array fabrication process.

There are several conventional array testing technologies currently available to LCD manufacturers in the market, the most prevalent of them being electrical LCD inspection using electro-optical transducers (modulators) as described, for example, in U.S. Pat. No. 4,983,911, incorporated herein by reference in its entirety. One exemplary LCD inspection device of this type is the Array Checker, commercially available from Photon Dynamics, Inc. an Orbotech company located in San Jose, California, USA. In particular, the aforesaid Array Checker inspection system employs a method called “VOLTAGE IMAGING®”, which utilizes a reflective liquid-crystal-based modulator configured to measure voltages on individual TFT array pixels. At the time of the inspection of the TFT array by the Array Checker the driving voltage patterns are applied to the TFT panels under test by a test pattern generator subsystem, and the resulting panel pixel voltages are measured by positioning the aforesaid electro-optical modulator in close proximity (typically around 50 microns) to the TFT array under test, and subjecting it to a high voltage square wave voltage pattern. For example, the amplitude of the voltage square wave pattern applied to the modulator could be 300V and frequency of 60 Hz. The electrical potential that is formed across the electro-optical modulator of the inspection system by virtue of its proximity of the pixels of the TFT array under test with applied driving voltage forces liquid crystals in the modulator to change their electric-field-dependent spatial orientation, locally changing their light transmittance across the modulator. In other words, the light transmittance of the modulator becomes representative of the voltages on array pixels in the proximity thereof. To capture the changed modulator transmittance, the modulator is illuminated with a light pulse and the light reflected by the modulator subjected to the panel voltages is imaged onto a voltage imaging optical subsystem (VIOS) camera, which acquires and digitizes the resulting image. The duration of the aforesaid light pulse could be, for example, 1 millisecond. An exemplary system and method for conversion of raw voltage image to LCD pixel map and detection of defects using the map is described in U.S. Pat. No. 7,212,024, incorporated herein by reference in its entirety.

However, because in accordance with the conventional inspection technology the driving voltages applied to the TFT panels under test during the inspection are not continuously monitored or controlled, any test pattern generator subsystem drift or changes in system or panel conditions can result in successive TFT panels being inspected under different conditions or unknowingly damaged during the inspection process. Without real-time monitoring, variations in the defect detection accuracy and repeatability will go unknown until the panels reach the cell process in the Fab. By the time the issues are discovered in the cell process, many thousands of panels may have been damaged or inspected under less than optimum conditions, resulting in financial losses for the manufacturer.

### SUMMARY OF THE INVENTION

The inventive methodology is directed to methods and systems that substantially obviate one or more of the above and other problems associated with conventional techniques for inspection of electronic circuits.

In accordance with one aspect of the embodiments described herein, there is provided an apparatus for identifying a defect in an electronic circuit, the apparatus incorporating: a circuit driving module configured to apply an electrical test signal to the electronic circuit; a defect detection module configured to identify the defect in the electronic circuit based at least on the applied electrical test signal; a signal monitoring module configured to measure the electrical test signal at the electronic circuit; and a control module operatively coupled to the signal monitoring module and the circuit driving module and configured to control at least the circuit driving module based on the electrical test signal measured at the electronic circuit.

In one or more embodiments, the electrical test signal is applied to the electronic circuit via a force line and wherein the signal monitoring module measures the electrical test signal at the force line.

In one or more embodiments, the signal monitoring module measures the electrical test signal at a return line electrically connected to the electronic circuit.

In one or more embodiments, the signal monitoring module measures a voltage of the electrical test signal.

In one or more embodiments, the control module controls an output voltage of the circuit driving module based on the voltage of the electrical test signal measured by the signal monitoring module.

In one or more embodiments, the signal monitoring module measures a current of the electrical test signal.

In one or more embodiments, the control module controls an output current of the circuit driving module based on the current of the electrical test signal measured by the signal monitoring module.

In one or more embodiments, the control module controls the circuit driving module additionally based on an output of the defect detection module.

In one or more embodiments, the control module controls at least one parameter of the circuit driving module within a predetermined parameter range.

In one or more embodiments, the control module controls at least one parameter of the circuit driving module to compensate for a drift in the electrical test signal applied by the circuit driving module to the electronic circuit.

In one or more embodiments, the control module controls at least one parameter of the circuit driving module to compensate for a change in at least one condition of the electronic circuit.

In one or more embodiments, the control module additionally controls the defect detection module based on the electrical test signal measured at the electronic circuit.

In one or more embodiments, the signal monitoring module is configured to continuously measure the electrical test signal at the electronic circuit.

In accordance with another aspect of the embodiments described herein, there is provided an apparatus for identifying a defect in an electronic circuit, the apparatus comprising: a circuit driving module configured to apply an electrical test signal to the electronic circuit; a defect detection module configured to identify the defect in the electronic circuit based at least on the applied electrical test signal; a signal monitoring module configured to measure the electrical test signal at the electronic circuit; and a signal analysis module operatively coupled to the signal monitoring module and configured to analyze the measured electrical test signal and determine whether a damage to the electronic circuit has occurred.

In one or more embodiments, the electrical test signal is applied to the electronic circuit via a force line and wherein the signal monitoring module measures the electrical test signal at the force line.

In one or more embodiments, the signal monitoring module measures the electrical test signal at a return line electrically connected to the electronic circuit.

In one or more embodiments, the signal monitoring module measures a voltage of the electrical test signal.

In one or more embodiments, the signal monitoring module measures a current of the electrical test signal.

In accordance with another aspect of the embodiments described herein, there is provided a method for identifying a defect in an electronic circuit, the method involving: applying an electrical test signal to the electronic circuit; identifying the defect in the electronic circuit using at least on the applied electrical test signal; measuring the electrical test signal at the electronic circuit; and controlling the electrical test signal applied to the electronic circuit based on the electrical test signal measured at the electronic circuit.

In one or more embodiments, the electrical test signal is applied to the electronic circuit via a force line and wherein the electrical test signal is measured at the force line.

In one or more embodiments, the electrical test signal is measured at a return line electrically connected to the electronic circuit.

In one or more embodiments, the electrical test signal comprises measuring a voltage of the electrical test signal.

In one or more embodiments, measuring the electrical test signal comprises measuring a current of the electrical test signal.

Additional aspects related to the invention will be set forth in part in the description which follows, and in part will be obvious from the description, or may be learned by practice of the invention. Aspects of the invention may be realized and attained by means of the elements and combinations of various elements and aspects particularly pointed out in the following detailed description and the appended claims.

It is to be understood that both the foregoing and the following descriptions are exemplary and explanatory only and are not intended to limit the claimed invention or application thereof in any manner whatsoever.

### BRIEF DESCRIPTION OF THE DRAWINGS

The accompanying drawings, which are incorporated in and constitute a part of this specification exemplify the embodiments of the present invention and, together with the description, serve to explain and illustrate principles of the inventive technique. Specifically:

FIG. 1 illustrates an exemplary embodiment of a system for test pattern generator drift compensation based on monitoring the signals on the force or sense lines between the inspection system and the display panel under test.

FIG. 2 illustrates another exemplary embodiment of a system for test pattern generator drift compensation based on monitoring the signals on the force or sense lines between the inspection system and the display panel under test as well as a closed-loop control mechanism.

FIG. 3 illustrates an example of a typical voltage square waveform applied to a panel under test, a current measured on the force line as well as a current pattern at a damaged display panel trace.

FIG. 4 illustrates a simplified block diagram of the exemplary embodiment of the control loop.

### DETAILED DESCRIPTION

In the following detailed description, reference will be made to the accompanying drawing(s), in which identical functional elements are designated with like numerals. The aforementioned accompanying drawings show by way of illustration, and not by way of limitation, specific embodiments and implementations consistent with principles of the present invention. These implementations are described in sufficient detail to enable those skilled in the art to practice the invention and it is to be understood that other implementations may be utilized and that structural changes and/or substitutions of various elements may be made without departing from the scope and spirit of the present invention. The following detailed description is, therefore, not to be construed in a limited sense. Additionally, the various embodiments of the invention as described may be implemented in the form of software running on a general purpose computer, in the form of specialized hardware, or any combination of software and hardware.

Various aspects of the present invention provide techniques for maintaining reliable and reproducible conditions for panel inspection, i.e. pixel and line defect detection, while at the same time preventing large-scale panel damage. Without such control and monitoring, successive panels may be inspected under different conditions or unknowingly damaged during the inspection process. Without real-time monitoring, variations in the defect detection accuracy and repeatability will go unknown until the panels reach the cell process in the Fab. By the time the issues are discovered in the cell process, many thousands of panels may have been damaged or inspected under less than optimum conditions, resulting in financial losses for the manufacturer.

Various embodiments of the described concepts provide a closed-loop control mechanism for the inspection system and a method to monitor displays under test in real-time. The inventive concepts described herein are applicable to inspecting all types of displays including LCD and OLED, both rigid and flexible, displays. The embodiments of the invention are also independent of backplane technology, e.g. a-Si, LTPS, IGZO, used in the displays.

In one or more embodiments, monitoring of the display under test can be performed in two ways, using either “force line” monitoring or “sense line” monitoring techniques described herein. Closed-loop control can also be set up using various measurements from the system such as, inspection site voltage, defect contrast, etc., as the input data to the control loop in order to dynamically adjust the panel testing conditions.

In one or more embodiments of the force line monitoring technique, measurements are performed at the output of the analog driving signals delivered to the panel under test. These signals are supplied to the panel via a signal path typically referred to as a “force line.” By continuously monitoring the force lines during test, the analog driving channel outputs can be adjusted in real-time to compensate any test pattern generator subsystem drift or changes in panel conditions. This results in a much more stable panel driving condition to every panel tested.

As would be appreciated by persons of skill in the art, without the aforesaid control and monitoring, if any drift exists in the test pattern generator subsystem, successive panels could be tested under slightly different driving conditions. On the other hand, by implementing the closed-loop control described in detail below, inspection of all panels will be done under as nearly identical driving conditions as possible.

On the other hand, in the embodiments of the sense line monitoring technique, measurements are performed at a return line connected to the panel under test. This return line is typically referred to as a “sense line.” This sense line can be monitored to detect any changes in the characteristics of the display panel under test. Changes to the display panel under test can be caused by a failure, e.g. contact pad burnout, within the panel or drift within the test pattern generator subsystem.

The aforesaid force line monitoring technique is described in more detail below. In one or more embodiments, the same type of monitoring may be implemented using the sense line, but this necessitates an additional signal path for connecting the inspection system to the panel under test. On the other hand, the force line monitoring will provide the same benefits as the sense line monitoring, without the necessity to add the aforesaid extra signal pathway. As stated previously, without either the force or sense line monitoring, if there is an undetected failure in the test pattern generator subsystem that is damaging panels under test, all panels that have been inspected will be damaged. In the case of the test pattern generator subsystem failure, the described embodiments can limit the damage to a single panel, thereby saving significant losses for the manufacturer.

In one or more embodiments, the real-time monitoring and closed-loop control techniques described herein are adapted for: catastrophic panel damage detection, adaptive panel driving, iterative system tuning, system drift compensation, and automated recipe tuning.

In one or more embodiments, system drift compensation is accomplished by monitoring the signals on the force or sense lines between the inspection system and the panel under test, as illustrated in FIG. 1. In FIG. 1, the force line (104) can be monitored while the panel is being inspected. The programmable device (101) will set the output of the digital-to-analog converter (DAC 102) and amplifier circuit (AMP 103) to the desired level based on the recipe input provided by the system user. During panel driving, the force line (104) is monitored for proper voltage delivery and current flow using the voltage measurement circuit (105) and the current measurement circuit (106), respectively. These two circuits are connected to the programmable device (101), through a multiplexer (MUX 107) and analog-to-digital converter (ADC 108). The ADC 108 converts the measured analog signals back into the digital domain, while the MUX 107 allows the programmable device (101) to monitor multiple force lines (104). If the voltage or current measured on the force line (104) begin to deviate from the user-specified values, the programmable device (101) is configured to control the driving signal using one or more lookup tables (LUT 109), for example, by automatically increasing or decreasing the current and voltage values until one or both return back to the user-specified levels.

In one or more embodiments, the user is enabled to set predetermined control limits such that the voltage and current can only be automatically adjusted by the programmable device (101) within a predetermined adjustment range. If the voltage or current measured on the force line (104) falls outside of the minimum or maximum values specified by the user, it may be an indication of catastrophic panel damage. Such catastrophic damage could include contact pad burnout or creation of shorts within the panel under test due to bad recipe setup or a hardware fault within the inspection system. In both of these cases, such panel damage would result in large amounts of current flowing from the test pattern generator subsystem into the panel. When the current measurement circuit (106) detects this large current flow on the force line (104) the system is configured to set off an alarm and shut down the inspection process. This will limit the damage to a single panel and alert the operator of a possible bad recipe setup or hardware failure within the inspection system.

In one or more embodiments, there is provided a closed-loop control mechanism that is established between the test pattern generator subsystem and the inspection head of the system (see FIG. 2). The closed-loop control mechanism can provide feedback based on the actual inspection measurements made at the panel. Examples of such measurements include, without limitation, the average voltage at the inspection site or the contrast of certain defect types detected in the inspection image. The received measurement results are used for adjusting the test pattern applied to the panel, which is referred to as “adaptive panel driving” as well as for auto-tuning of the inspection recipes based on the panel testing results.

An exemplary embodiment of the aforesaid closed-loop control mechanism is illustrated in FIG. 2. The shown exemplary embodiment of the closed-loop control mechanism operates by collecting panel inspection results (210) and feeding those results back into the programmable device (101). The programmable device (101) can use the DAC (102) to modify the output of the AMP (103) by an incremental amount, thereby modifying the panel inspection result (210). In one or more embodiments, this process can be repeated until the desired panel inspection result (210) is achieved, for one or multiple panels.

### Real-Time Force Line Monitoring

One or more embodiments of the described techniques provide the ability to detect display panel shorts that may develop during the panel inspection process. One exemplary technique for detecting such damage involves monitoring the force line current measurement circuit while testing the display panel. Specifically, FIG. 3 shows an example of a typical voltage square waveform (301) applied to a representative capacitive load, or panel under test. The square wave can switch between two or more nominal positive or negative voltages. In this example, the square wave (301) is switching between 0 v and a nominal maximum positive voltage, X v. During normal panel driving, the current measured on the force line should have a predicable and repeatable shape (302). As the voltage is switched positive, the current will quickly rise to the operator defined current limiting setting, Y mA. Once the voltage stabilizes, the current will gradually reduce to nearly 0 mA while the voltage remains at X v. This behavior repeats for each voltage pulse in the pattern. When panel damage occurs, this current trace will look noticeably different. The damaged panel current trace (303) shows the expected current measurement from a force line driving into a panel short. Instead of gradually returning towards 0 mA after the initial voltage pulse is applied, the channel will continue to output voltage at the operator defined current limit for the duration of the voltage pulse. The current will only return to 0 mA when the pulse is switched off. In this case, the programmable unit 101 will detect, through the current measurement circuit, that the channel is operating at the current limit for an extended period of time. The programmable unit will shut down the driving channel and alarm the system. The alarm can alert the operator of a damaged panel and recommend checking the system for hardware failures or that changes be made to the pattern tuning. It should be noted that all monitoring is done on a per channel basis and that a typical system will have many independent channels. Each channel in the system is independently monitored and controlled, as described above.

### Closed-Loop Control

One or more embodiments of the described techniques provide the capability to operate the inspection system in a closed-loop control mode. In this mode of operation, the system can use inspection results as the input to the control loop. If the system begins to sense drift in the measurements, the control loop can modify one or more of the inspection parameters to compensate for the drift and return the system back to a state of providing repeatable and reproducible inspection conditions. FIG. 4 illustrates a simplified block diagram of an exemplary embodiment of the control loop. In the shown example, the inspection head (401) performs active inspection of the device under test (402). The inspection head (401) is connected to a data processing unit (403), which is responsible for collection and interpretation of the collected data. The data processing unit (403) provides results in real-time to the operator as well as saves representative data over time for use in monitoring system drift. The data processing unit (403) is connected to the programmable device (404). The programmable device can interpret the data collected over time by the data processing unit (403) and determine if the system is drifting. If system drift is detected the programmable device (404) can make changes to the outputs of any number of subsystem supply units (405, 406) to counteract the system drift and return the system to a stable mode of operation. FIG. 4 shows subsystem supply unit 1 (405) that can adjust panel driving conditions (e.g. driving voltage, current, pulse width, etc.) and subsystem supply unit 2 (406) that can adjust sensor conditions (e.g. sensor bias voltage, illumination intensity, etc.). Although not shown, the control loop can be setup to connect the programmable device (404) to tune additional subsystems, and example of which would be the stage motion subsystem in which X, Y, and Z motion axes could adjusted based on inspection results to compensate for drift in the motion system. In one or more embodiments, the system contains multiple sets of independent channels and subsystem supply units. The closed-loop control function can apply corrections to all of these groups based on individual or common feedback.

It should be noted that the inventive techniques described herein are not limited to the inspection of display panels. The embodiments of the inventive concepts may be utilized in inspection of other electronic devices, including, without limitation, printed circuit boards (PCBs), semiconductor circuits (e.g. on wafers) as well as other such devices.

Finally, it should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein. The present invention has been described in relation to particular examples, which are intended in all respects to be illustrative rather than restrictive. Those skilled in the art will appreciate that many different combinations of hardware, software, and firmware will be suitable for practicing the present invention.

Moreover, other implementations of the invention will be apparent to those skilled in the art from consideration of the specification and practice of the invention disclosed herein. Various aspects and/or components of the described embodiments may be used singly or in any combination in the inspection system. It is intended that the specification and examples be considered as exemplary only, with a true scope and spirit of the invention being indicated by the following claims.

What is claimed is:

1. An apparatus for identifying a defect in an electronic circuit, the apparatus comprising:
a. a circuit driving module configured to apply an electrical test signal to the electronic circuit;
b. a defect detection module configured to identify the defect in the electronic circuit based at least on the applied electrical test signal;
c. a signal monitoring module configured to measure the electrical test signal at the electronic circuit; and
d. a control module operatively coupled to the signal monitoring module and the circuit driving module and configured to control at least the circuit driving module based on the electrical test signal measured at the electronic circuit.

2. The apparatus of claim 1, wherein the electrical test signal is applied to the electronic circuit via a force line and wherein the signal monitoring module measures the electrical test signal at the force line.

3. The apparatus of claim 1, wherein the signal monitoring module measures the electrical test signal at a return line electrically connected to the electronic circuit.

4. The apparatus of claim 1, wherein the signal monitoring module measures a voltage of the electrical test signal.

5. The apparatus of claim 4, wherein the control module controls an output voltage of the circuit driving module based on the voltage of the electrical test signal measured by the signal monitoring module.

6. The apparatus of claim 1, wherein the signal monitoring module measures a current of the electrical test signal.

7. The apparatus of claim 6, wherein the control module controls an output current of the circuit driving module based on the current of the electrical test signal measured by the signal monitoring module.

8. The apparatus of claim 1, wherein the control module controls the circuit driving module additionally based on an output of the defect detection module.

9. The apparatus of claim 1, wherein the control module controls at least one parameter of the circuit driving module within a predetermined parameter range.

10. The apparatus of claim 1, wherein the control module controls at least one parameter of the circuit driving module to compensate for a drift in the electrical test signal applied by the circuit driving module to the electronic circuit.

11. The apparatus of claim 1, wherein the control module controls at least one parameter of the circuit driving module to compensate for a change in at least one condition of the electronic circuit.

12. The apparatus of claim 1, wherein the control module additionally controls the defect detection module based on the electrical test signal measured at the electronic circuit.

13. The apparatus of claim 1, wherein the signal monitoring module is configured to continuously measure the electrical test signal at the electronic circuit.

14. An apparatus for identifying a defect in an electronic circuit, the apparatus comprising:
a. a circuit driving module configured to apply an electrical test signal to the electronic circuit;
b. a defect detection module configured to identify the defect in the electronic circuit based at least on the applied electrical test signal;
c. a signal monitoring module configured to measure the electrical test signal at the electronic circuit; and
d. a signal analysis module operatively coupled to the signal monitoring module and configured to analyze the measured electrical test signal and determine whether a damage to the electronic circuit has occurred.

15. The apparatus of claim 14, wherein the electrical test signal is applied to the electronic circuit via a force line and wherein the signal monitoring module measures the electrical test signal at the force line.

16. The apparatus of claim 14, wherein the signal monitoring module measures the electrical test signal at a return line electrically connected to the electronic circuit.

17. The apparatus of claim 14, wherein the signal monitoring module measures a voltage of the electrical test signal.

18. The apparatus of claim 14, wherein the signal monitoring module measures a current of the electrical test signal.

19. A method for identifying a defect in an electronic circuit, the method comprising:
a. applying an electrical test signal to the electronic circuit;
b. identifying the defect in the electronic circuit using at least on the applied electrical test signal;
c. measuring the electrical test signal at the electronic circuit; and
d. controlling the electrical test signal applied to the electronic circuit based on the electrical test signal measured at the electronic circuit.

20. The method of claim 19, wherein the electrical test signal is applied to the electronic circuit via a force line and wherein the electrical test signal is measured at the force line.

21. The method of claim 19, wherein the electrical test signal is measured at a return line electrically connected to the electronic circuit.

22. The method of claim 19, wherein measuring the electrical test signal comprises measuring a voltage of the electrical test signal.

23. The method of claim 19, wherein measuring the electrical test signal comprises measuring a current of the electrical test signal.
